(19) United States
(12) Patent Application Publication
(10) Pub. No.: US 2026/0229848 A1
(43) Pub. Date: Aug. 6, 2026

(54) SURFACE EMITTING LASER, EYEBALL-TILT-POSITION DETECTING DEVICE, DISTANCE MEASURING DEVICE, DISPLAY DEVICE, AND ATOMIC OSCILLATOR

(71) Applicant: Ryoichiro Suzuki, Miyagi (JP)

(72) Inventor: Ryoichiro Suzuki, Miyagi (JP)

(73) Assignee: Ricoh Company, Ltd., Tokyo (JP)

(21) Appl. No.: 19/445,023

(22) Filed: Jan. 9, 2026

(30) Foreign Application Priority Data
Jan. 31, 2025 (JP) 2025-015600
Oct. 23, 2025 (JP) 2025-178715

(51) Int. Cl. H01S 5/183; G01S 17/894; G02B 27/00; G02B 27/01; G04F 5/14; H01S 5/343

(52) U.S. Cl. CPC H01S 5/18377; G01S 17/894; G02B 27/0093; G04F 5/145; H01S 5/18311; H01S 5/18358; H01S 5/343; G02B 27/0172

(57) ABSTRACT

A surface emitting laser includes an inclined substrate; a first reflecting mirror over the inclined substrate in an emission direction; a resonator over the first reflecting mirror in the emission direction; and a second reflecting mirror over the resonator in the emission direction. The resonator includes: a first spacer layer over the first reflecting mirror in the emission direction; an active layer over the first spacer layer in the emission direction; and a second spacer layer over the active layer in the emission direction. At least one of the first spacer layer or the second spacer layer has compressive strain. The resonator has a net strain of +4.5%·nm or more and +93.6%·nm or less.

### CROSS-REFERENCE TO RELATED APPLICATIONS

This patent application is based on and claims priority pursuant to 35 U.S.C. § 119(a) to Japanese Patent Application No. 2025-015600, filed on Jan. 31, 2025 and Japanese Patent Application No. 2025-178715, filed on Oct. 23, 2025, in the Japan Patent Office, the entire disclosure of which is hereby incorporated by reference herein.

### BACKGROUND

### Technical Field

The present disclosure relates to a surface emitting laser, an eyeball-tilt-position detecting device, a distance measuring device, a display device, and an atomic oscillator.

### Related Art

A vertical cavity surface emitting laser (VCSEL) is a semiconductor laser that can emit light perpendicularly to a substrate surface.

### SUMMARY

The present disclosure described herein provides a surface emitting laser includes an inclined substrate; a first reflecting mirror over the inclined substrate in an emission direction; a resonator over the first reflecting mirror in the emission direction; and a second reflecting mirror over the resonator in the emission direction. The resonator includes: a first spacer layer over the first reflecting mirror in the emission direction; an active layer over the first spacer layer in the emission direction; and a second spacer layer over the active layer in the emission direction. At least one of the first spacer layer or the second spacer layer has compressive strain. The resonator has a net strain of +4.5%·nm or more and +93.6%·nm or less.

The present disclosure described herein provides an eyeball-tilt-position detecting device includes the surface emitting laser; and a photodetector to detect reflected light emitted from the surface emitting laser and reflected from an eyeball.

The present disclosure described herein provides a distance measuring device includes the surface emitting laser; and a photodetector to detect reflection light emitted from the surface emitting laser and reflected from an object.

The present disclosure described herein provides a display device including the above-described surface emitting laser.

The present disclosure described herein provides an atomic oscillator includes the surface emitting laser; an alkali metal cell in which an alkali metal is sealed; and a light detector to detect light emitted from the surface emitting laser and passed through the alkali metal cell.

### BRIEF DESCRIPTION OF THE DRAWINGS

A more complete appreciation of embodiments of the present disclosure and many of the attendant advantages and features thereof can be readily obtained and understood from the following detailed description with reference to the accompanying drawings, wherein:

FIG. 1 is a cross-sectional view schematically illustrating an example of a surface emitting laser according to a first embodiment;

FIG. 2 is a schematic diagram illustrating an example of an inclined substrate of the surface emitting laser according to the first embodiment;

FIG. 3 is a cross-sectional view schematically illustrating an example of an active layer included in the surface emitting laser according to the first embodiment;

FIG. 4 is a graph presenting an example of the relationship between the net strain in a resonator and the polarization ratio of laser beams emitted from the surface emitting laser;

FIG. 5 is a graph presenting an example of the relationship between the area of a selective oxidation region in a current confinement layer of Example 1 and the polarization ratio of laser beams emitted from the surface emitting laser;

FIG. 6 is a graph presenting an example of the relationship between the area of the selective oxidation region in the current confinement layer of Example 1 and the polarization direction of laser beams emitted from the surface emitting laser;

FIG. 7 is a cross-sectional view schematically illustrating an example of a surface emitting laser according to a second embodiment;

FIG. 8 is a cross-sectional view schematically illustrating an example of a surface emitting laser according to a third embodiment;

FIG. 9 is a cross-sectional view schematically illustrating an example of an active layer included in the surface emitting laser according to the third embodiment;

FIG. 10 is a cross-sectional view schematically illustrating an example of a surface emitting laser according to a fourth embodiment;

FIG. 11 is a plan view illustrating an example of a pair of dielectric films (basic example) included in the surface emitting laser according to the fourth embodiment;

FIG. 12 is a plan view illustrating an example of a pair of dielectric films according to Modification 1;

FIG. 13 is a plan view illustrating an example of a dielectric film according to Modification 2;

FIG. 14 is a graph presenting polarization ratios of the basic example, Modification 1, and Modification 2;

FIG. 15 is a plan view schematically illustrating an example of an eyeball-tilt-position detecting device according to a fifth embodiment;

FIG. 16 is a block diagram schematically illustrating an example of a distance measuring device according to a sixth embodiment;

FIG. 17 is a diagram schematically illustrating an example of a head mount display according to a seventh embodiment;

FIG. 18 is a diagram schematically illustrating an example of an atomic oscillator according to a seventh embodiment;

FIG. 19 is a diagram illustrating an example of an atomic energy level for explaining the coherent population trapping (CPT);

FIG. 20 is a diagram illustrating an example of an output wavelength at the time of modulation of a surface emitting laser; and

FIG. 21 is a diagram illustrating an example of the relationship between modulation frequency and an amount of transmitted light.

The accompanying drawings are intended to depict embodiments of the present disclosure and should not be interpreted to limit the scope thereof. The accompanying drawings are not to be considered as drawn to scale unless explicitly noted. Also, identical or similar reference numerals designate identical or similar components throughout the several views.

### DETAILED DESCRIPTION

In describing embodiments illustrated in the drawings, specific terminology is employed for the sake of clarity. However, the disclosure of this specification is not intended to be limited to the specific terminology so selected and it is to be understood that each specific element includes all technical equivalents that have a similar function, operate in a similar manner, and achieve a similar result.

Referring now to the drawings, embodiments of the present disclosure are described below. As used herein, the singular forms “a,” “an,” and “the” are intended to include the plural forms as well, unless the context clearly indicates otherwise.

A surface emitting laser has features such as low cost, low power consumption, a small size, and high performance, and ease of two-dimensional arrangement, as compared to an edge emitting semiconductor laser. Applications of the surface emitting laser include a wide range of applications such as a light source for exposure of a photosensitive drum included in an electrophotographic image forming apparatus, a light source of an optical communication device, and a light source of a sensor device.

In one example of related art, a surface emitting laser including an active layer disposed on an inclined substrate and having increased strain is known.

For the surface emitting laser, it is desirable to increase the polarization ratio of laser beams emitted from the surface emitting laser.

According to one aspect of the present disclosure, a surface emitting laser that increases the polarization ratio of laser beams can be provided.

As a premise of describing an embodiment, an example of factors that cause polarization directions of laser beams emitted from a general surface emitting laser (hereinafter, simply referred to as “polarization directions” in some cases) to be random (unstable) without being aligned in one direction will be described. When the surface emitting laser is viewed from a laser emission surface (for example, an upper surface) side, that is, in a plan view, the surface emitting laser has a symmetrical element structure or a symmetrical band structure of an active layer. Thus, laser oscillation may occur regardless of the direction of the electric field in the resonator including the active layer. This is considered as one of factors that cause the polarization directions to be random (unstable) without being aligned in one direction.

As an example of a method for stabilizing the polarization directions, there is a method of forming a fine periodic structure (surface relief) having a sub-wavelength size on the laser emission surface of the surface emitting laser. With this method, the resonator has anisotropic reflectivity, and hence the polarization directions of laser beams can be controlled to a desired direction and stabilized. However, with this method, the fine periodic structure is to be manufactured with high precision and high throughput, possibly leading to a decrease in yield.

As another example of the method for stabilizing the polarization directions, there is a method of forming each semiconductor layer included in the resonator on an inclined substrate. With this method, for example, the band structure of the active layer in a plan view can be made asymmetric, and the polarization angle of laser beams can be stabilized at 900 or 180°. With this configuration, the polarization directions of laser beams can be controlled to a desired direction and stabilized while a decrease in yield is prevented. A surface emitting laser according to an embodiment includes a resonator disposed on an inclined substrate.

With the above-described method, the polarization directions of laser beams can be stabilized in a desired direction.

However, in order to further stabilize the polarization directions of laser beams, it is desirable to reduce laser beams emitted in a direction different from the specific direction to increase the polarization ratio (cross-polarization suppression ratio). In the one example of related art, a high polarization ratio is obtained due to the increased strain of the active layer; however, there is a problem that the emission wavelength increases with the increase in strain of the active layer. Thus, an increase in polarization ratio by an approach different from the increase in strain of the active layer is desired.

Embodiments of the present disclosure are described below with reference to the accompanying drawings. Note that in the description and the drawings of the embodiments of the present disclosure, like reference signs are given to elements with substantially the same functional configurations. Accordingly, overlapping descriptions are omitted where appropriate. The embodiments described below are illustrative of a spectroscope for embodying the technical idea of the present disclosure, and the present disclosure is not limited to the embodiments described below. In the drawings described below, directions may be indicated by an X-axis, a Y-axis, and a Z-axis. The X-axis, the Y-axis, and the Z-axis are directions orthogonal to each other. The X-axis direction corresponds to the width direction of the surface emitting laser. The Y-axis direction corresponds to the depth direction of the surface emission. The Z-axis direction corresponds to the thickness direction of the surface emitting laser. The X-axis direction and the Y-axis direction may be referred to as an “in-plane direction.” The Z-axis direction may be referred to as a “direction perpendicular to a plane.” Note that in the description and the drawings of the embodiments of the present disclosure, the term “disposed” is not limited to a case of being in direct contact with an object, and includes a case of being indirectly disposed, for example, via another member.

### First Embodiment

### General Arrangement

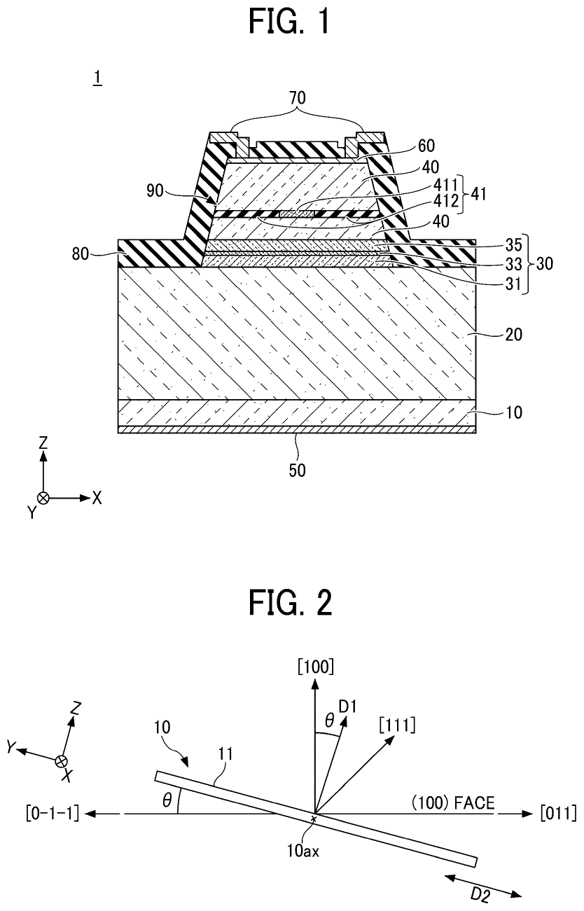

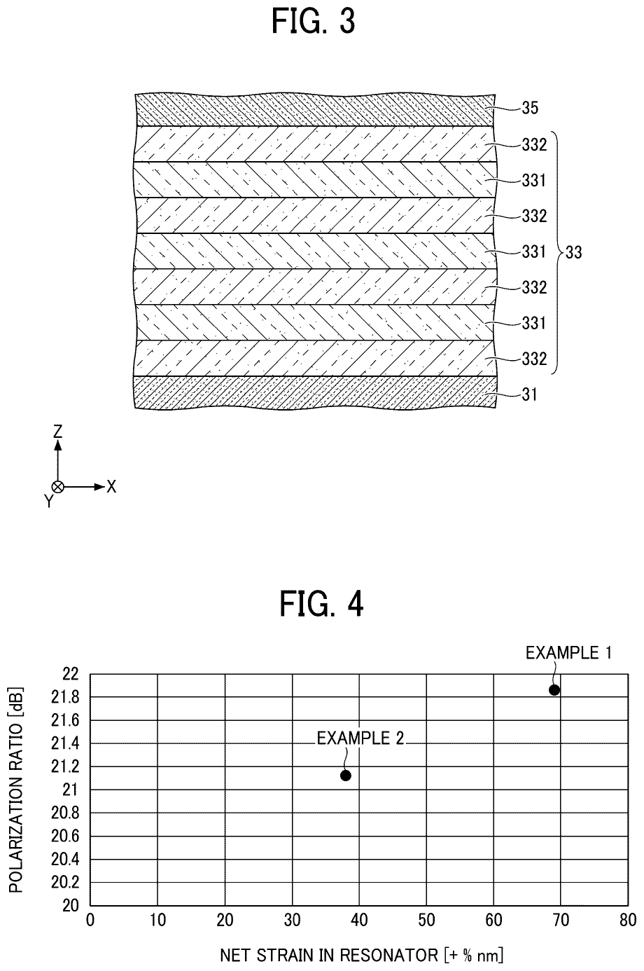

A surface emitting laser 1 according to a first embodiment will be described referring to FIGS. 1 to 3. FIG. 1 is a cross-sectional view schematically illustrating an example of the surface emitting laser 1 according to the first embodiment. FIG. 2 is a schematic diagram illustrating an example of an inclined substrate 10 of the surface emitting laser 1 according to the first embodiment. FIG. 3 is a cross-sectional view schematically illustrating an example of an active layer 33 included in the surface emitting laser 1 according to the first embodiment.

As illustrated in FIG. 1, the surface emitting laser 1 includes the inclined substrate 10, a lower reflecting mirror 20, a resonator 30, and an upper reflecting mirror 40. The surface emitting laser 1 may further include other components such as a lower electrode 50, a contact layer 60, an upper electrode 70, and an insulating film 80.

In the example illustrated in FIG. 1, the surface emitting laser 1 includes a mesa structure 90 including a lower spacer layer 31, an active layer 33, and an upper spacer layer 35 that are included in the resonator 30, and the upper reflecting mirror 40. Hereinafter, each component included in the surface emitting laser 1 will be described.

The inclined substrate 10 has a main surface 11 as a +Z-side surface. As illustrated in FIG. 2, the inclined substrate 10 is a substrate in which a normal direction D1 of the main surface 11 is inclined by θ[°] toward, for example, the [1 1 1] direction of crystal orientation with respect to the [1 0 0] direction of crystal orientation. Hereinafter, reference character θ is referred to as an “inclination angle θ.” The range of the inclination angle θ is, for example, 2° or more and 20° or less. However, the range of the inclination angle θ is not limited thereto.

In the example illustrated in FIG. 2, an inclination axis 10ax of the inclined substrate 10 is parallel to the X-axis direction. A direction orthogonal to each of the normal direction D1 of the main surface 11 and the direction of the inclination axis 10ax of the inclined substrate 10 is referred to as an “inclination direction D2.” In the example illustrated in FIG. 2, the Y-axis direction is the inclination direction D2. However, the inclination direction D2 is not limited to the Y-axis direction. The normal direction D1 of the main surface 11 of the inclined substrate 10 may be inclined toward a direction different from the [1 1 1] direction of crystal orientation.

With the surface emitting laser 1 including the inclined substrate 10, the active layer 33 having an optical gain anisotropic in the inclination direction D2 and in the direction orthogonal to the inclination direction D2 in a plan view can be obtained. With this configuration, the polarization directions of laser beams emitted from the surface emitting laser 1 can be easily controlled to a specific direction.

The inclined substrate 10 is made of, for example, n-GaAs. However, the inclined substrate 10 may be a substrate made of another semiconductor material such as GaN or AlN. As the inclined substrate 10, for example, a template in which a semiconductor layer is formed on a different type of substrate may be used. Examples of the different type of substrate include a sapphire substrate, a Si substrate, a GaAs substrate, and a SiC substrate.

The lower reflecting mirror 20 is disposed on the inclined substrate 10. The lower reflecting mirror 20 is a multilayer-film reflecting mirror in which a high refractive-index layer and a low refractive-index layer are alternately stacked. The lower reflecting mirror 20 includes, for example, 35.5 pairs of a high refractive-index layer made of n-Al_{0.1}Ga_{0.9}As and a low refractive-index layer made of n-Al_{0.9}Ga_{0.1}As. When reference character X represents the oscillation wavelength, for example, each high refractive-index layer and each low refractive-index layer in the lower reflecting mirror 20 are formed such that the optical thickness of each layer is λ/4. The wavelength λ is a value in vacuum. The optical thickness is a value obtained by multiplying the physical thickness of a substance by the refractive index of the substance.

The resonator 30 is disposed on the lower reflecting mirror 20. As illustrated in FIG. 1, the resonator 30 includes the lower spacer layer 31, the active layer 33, and the upper spacer layer 35. The lower spacer layer 31 is disposed on the lower reflecting mirror 20. The active layer 33 is disposed on the lower spacer layer 31. The upper spacer layer 35 is disposed on the active layer 33. The active layer 33 is interposed between the lower spacer layer 31 and the upper spacer layer 35 in the Z-axis direction. Light in the active layer 33 is reflected by each of the lower reflecting mirror 20 and the upper reflecting mirror 40 and reciprocates in the resonator 30.

In the resonator 30, at least one of the lower spacer layer 31 and the upper spacer layer 35 has compressive strain included in lattice strain. More specifically, one of the lower spacer layer 31 and the upper spacer layer 35 may have compressive strain, or both the lower spacer layer 31 and the upper spacer layer 35 may have compressive strain. One of the lower spacer layer 31 and the upper spacer layer 35 having no compressive strain may have no lattice strain or may have tensile strain. The active layer 33 desirably has lattice strain. The lattice strain of the active layer 33 may be compressive strain or tensile strain.

The lattice strain is strain generated in a growth layer (for example, the lower spacer layer 31, the active layer 33, the upper spacer layer 35) due to lattice mismatch between the growth layer and a growth substrate (for example, the inclined substrate 10). When the lattice constant of the growth layer is larger than the lattice constant of the growth substrate, compressive strain is generated. In contrast, when the lattice constant of the growth layer is smaller than the lattice constant of the growth substrate, tensile strain is generated.

A net strain E in the resonator 30 is +4.5%·nm or more and +93.6%·nm or less. The net strain E in the resonator 30 may be not less than +4.5%·nm and not more than +93.0%·nm. The net strain E in the resonator 30 is the sum total of net strains Ei of the layers included in the resonator 30. The net strain Ei of each layer is calculated as the product of an amount εi[%] of strain in the in-plane direction of the layer and a thickness ti [nm] of the layer.

When the resonator 30 includes k layers, the net strain E in the resonator 30 can be calculated using Equation (1) below.

$$E = {\sum }_{1}^{k} E i = {\sum }_{1}^{k} ( {ε}_{i} \cdot {t}_{i} ) \qquad ( 1 )$$

For example, in the resonator 30, when the number of layers included in the lower spacer layer 31 is p, the number of layers included in the active layer 33 is q, and the number of layers included in the upper spacer layer 35 is r, the number (k) of layers included in the resonator 30 is [p+q+r]. When the resonator 30 further includes another layer, the number (k) of layers included in the resonator 30 is a number obtained by further adding the number of layers included in the other layer.

The amount εi of strain in the in-plane direction is calculated by Equation (2) below.

$${ε}_{i} = \frac{{a}_{epi} - {a}_{sub}}{{a}_{sub}} \qquad ( 2 )$$

In the equation, reference character aₑₚᵢ represents a lattice constant of a layer corresponding to the growth layer. Reference character a_{sub} represents a lattice constant of the growth substrate (for example, the inclined substrate 10). When the lattice strain generated in a layer corresponding to the growth layer is compressive strain, the value of the amount εi of strain in the in-plane direction of the layer is a positive value. When the lattice strain generated in a layer corresponding to the growth layer is tensile strain, the value of the amount εi of strain in the in-plane direction of the layer is a negative value. The amount εi of strain in the in-plane direction is hereinafter simply referred to as an “amount εi of strain.”

When the net strain E in the resonator 30 is +4.5%·nm or more and +93.6%·nm or less, the polarization directions of laser beams can be controlled to a desired direction and stabilized. In addition, the polarization ratio can be increased. The polarization ratio is a ratio between the intensity of light in a desired polarization direction and the intensity of light in a direction orthogonal to the desired polarization direction. As the polarization ratio is higher, the intensity of light in the desired polarization direction is higher than the intensity of light in the direction orthogonal to the desired polarization direction. When the net strain E in the resonator 30 is +4.5%·nm or more and +93.0%·nm or less, the polarization directions of laser beams can be controlled to a desired direction and stabilized.

In contrast, when the net strain E in the resonator 30 is less than +4.5%·nm, the stability of the polarization directions can be increased; however, the polarization ratio may not be sufficiently increased. When the net strain E in the resonator 30 exceeds +93.6%·nm, crystal defects, dislocations, and so forth (hereinafter collectively referred to as “defects and so forth”) are more likely to be generated in the resonator 30.

The net strain E in the resonator 30 is more preferably +10.0%·nm or more and +90.0%·nm or less and further preferably +59.0%·nm or more and +79.0%·nm or less. With this configuration, the polarization ratio can be further increased.

With the present embodiment, at least one of the lower spacer layer 31 and the upper spacer layer 35 has compressive strain, and the net strains Ei of the layers included in the resonator 30 are adjusted. Thus, the net strain E in the resonator 30 can be adjusted to fall within a desired range. That is, at least one of the amount εi of strain and the thickness ti of the one of the lower spacer layer 31 and the upper spacer layer 35 having compressive strain is adjusted. Thus, the net strain E in the resonator 30 can be adjusted to fall within a desired range. With this configuration, the polarization directions of laser beams can be controlled to a desired direction and stabilized. In addition, the polarization ratio can be increased. The polarization ratio of the surface emitting laser 1 is preferably 20 dB or more. However, the polarization ratio of the surface emitting laser 1 is not limited thereto. The same applies to the polarization ratio in second and subsequent embodiments.

With the active layer 33 having lattice strain, the net strain E in the resonator 30 can be finely adjusted, and the wavelengths of laser beams emitted from the surface emitting laser 1 can be adjusted. With this configuration, the polarization directions of laser beams can be controlled to a desired direction and stabilized. In addition, while the polarization ratio is increased, the wavelengths of laser beams can be adjusted in accordance with the application of the surface emitting laser 1. Depending on the application of the surface emitting laser 1, the wavelengths of laser beams may be desired to be in a specific wavelength band. In this case, the net strain Ei of one of the lower spacer layer 31 and the upper spacer layer 35 having compressive strain is adjusted without adjustment of the net strain Ei of the active layer 33. Thus, the polarization directions of laser beams can be controlled to a desired direction and stabilized, and the polarization ratio can be increased.

The lower spacer layer 31 is made of, for example, a semiconductor material such as GaInP or AlGaInP. The lower spacer layer 31 may include an impurity having the conductivity type of the n-type or the p-type.

When the lower spacer layer 31 has compressive strain, the amount εi of strain of the lower spacer layer 31 is preferably +0.05% or more and +0.3% or less. The amount εi of strain of the lower spacer layer 31 is more preferably 0.05% or more and 0.2% or less. When the amount εi of strain of the lower spacer layer 31 is +0.05% or more and +0.3% or less, the polarization directions of laser beams can be controlled to a desired direction and stabilized while defects and so forth generated in the lower spacer layer 31 are reduced. In addition, the polarization ratio can be increased. However, the amount εi of strain of the lower spacer layer 31 is not limited thereto.

As illustrated in FIG. 3, the active layer 33 includes a quantum well layer 331 and a barrier layer 332.

The active layer 33 desirably has, for example, a multiple quantum well structure in order to obtain high emission efficiency. That is, the active layer 33 desirably includes a plurality of quantum well layers 331 and a plurality of barrier layers 332 that are alternately stacked. Examples of the material of the quantum well layer 331 include GaInAs, AlGaAs, GaAs, and GaInP. Examples of the material of the barrier layer 332 include GaInP and AlGaInP.

The quantum well layer 331 of the active layer 33 desirably has lattice strain. The quantum well layer 331 may have compressive strain or tensile strain. When the quantum well layer 331 has no lattice strain or has compressive strain, the amount εi of strain of the quantum well layer 331 is preferably 0% or more and +1.5% or less. The amount εi of strain of the quantum well layer 331 is more preferably +0.2% or more and +1.0% or less. When the amount εi of strain of the quantum well layer 331 is 0% or more and +1.5% or less, the surface emitting laser 1 can be used as, for example, a light emitting device that emits light on the long-wavelength side (for example, near infrared light having a wavelength of 1000 nm or less). With this configuration, the surface emitting laser 1 can be used as a light emitting device that emits near infrared light, the demand for which has increased in recent years, while reducing defects and so forth generated in the quantum well layer 331. In addition, a light receiver made of Si that is less likely to include noise of sunlight can be used as a light receiver that receives laser beams from the surface emitting laser 1.

When the quantum well layer 331 has no lattice strain or has tensile strain, the amount εi of strain of the quantum well layer 331 is preferably −1.5% or more and 0% or less. The amount εi of strain of the quantum well layer 331 is more preferably −1.0% or more and −0% or less. When the amount εi of strain of the quantum well layer 331 is −1.5% or more and 0% or less, the surface emitting laser 1 can be used as, for example, a light emitting device that emits visible light while reducing defects and so forth generated in the quantum well layer 331.

The thickness of the quantum well layer 331 is, for example, 4 nm or more and 10 nm or less. However, the thickness of the quantum well layer 331 is not limited thereto.

The barrier layer 332 of the active layer 33 may have lattice strain or may have no lattice strain. The thickness of the barrier layer 332 is, for example, 4 nm or more and 10 nm or less. However, the thickness of the barrier layer 332 is not limited thereto.

The upper spacer layer 35 is made of, for example, a semiconductor material such as GaInP or AlGaInP. The upper spacer layer 35 may include an impurity having the conductivity type of the n-type or the p-type.

When the upper spacer layer 35 has compressive strain, the amount εi of strain of the upper spacer layer 35 is preferably +0.05% or more and +0.3% or less. The amount εi of strain of the upper spacer layer 35 is more preferably +0.05% or more and +0.2% or less. When the amount εi of strain of the upper spacer layer 35 is +0.05% or more and +0.3% or less, the polarization directions of laser beams can be controlled to a desired direction and stabilized while defects and so forth generated in the upper spacer layer 35 are reduced. In addition, the polarization ratio can be increased. However, the amount εi of strain of the upper spacer layer 35 is not limited thereto.

The upper reflecting mirror 40 is disposed on the resonator 30. The upper reflecting mirror 40 is a multilayer-film reflecting mirror in which a high refractive-index layer and a low refractive-index layer are alternately stacked. The upper reflecting mirror 40 includes, for example, 20 pairs of a high refractive-index layer made of p-Al_{0.1}Ga_{0.9}As and a low refractive-index layer made of p-Al_{0.9}Ga_{0.1}As. When reference character X represents the oscillation wavelength, for example, each high refractive-index layer and each low refractive-index layer in the upper reflecting mirror 40 are formed such that the optical thickness of each layer is λ/4.

As illustrated in FIG. 1, the upper reflecting mirror 40 may include a current confinement layer 41. The current confinement layer 41 includes a non-oxidation region 411 made of, for example, AlAs, and a selective oxidation region 412 made of, for example, AlₓO_{y}. The non-oxidation region 411 is surrounded by the selective oxidation region 412. With the upper reflecting mirror 40 including the current confinement layer 41, a current path to the active layer 33 can be limited.

The lower electrode 50 is disposed below (on the −Z side of) the inclined substrate 10. The upper electrode 70 is disposed above (on the +Z side of) the upper reflecting mirror 40. Each of the lower electrode 50 and the upper electrode 70 includes, for example, a Ti layer and an Au layer. However, the configuration of the lower electrode 50 and the upper electrode 70 is not limited thereto.

When a voltage is applied between the lower electrode 50 and the upper electrode 70, carriers are injected into the active layer 33. The active layer 33 confines the injected carriers and emits light. When the laser oscillation condition is satisfied, light generated in the active layer 33 is amplified, and laser beams are emitted from the surface emitting laser 1.

In the example illustrated in FIG. 1, the contact layer 60 is disposed on the upper reflecting mirror 40. In the present embodiment, the contact layer 60 is made of p-GaAs. However, the contact layer 60 may be made of a transparent conductive material such as indium tin oxide (ITO) or F-doped tin oxide (FTO).

The insulating film 80 covers a surface of the mesa structure 90. The insulating film 80 can also cover the upper surface of the contact layer 60 except for a connection region between the contact layer 60 and the upper electrode 70. The insulating film 80 is desirably made of a material that can transmit laser beams emitted from the active layer 33. Examples of the material of the insulating film 80 include dielectrics such as SiNₓ, SiOₓ, TiOₓ, and SiON (for example, SiN, SiO₂, and Ta₂O₅).

### EXAMPLES

Next, the surface emitting laser 1 according to the first embodiment will be described in more detail using examples. However, the scope of the present disclosure is not limited to the following examples.

First, referring to FIG. 4, an example of the relationship between the net strain E in the resonator 30 and the polarization ratio of laser beams emitted from the surface emitting laser 1 will be described. FIG. 4 is a graph presenting an example of the relationship between the net strain E in the resonator 30 and the polarization ratio of laser beams emitted from the surface emitting laser 1. The horizontal axis of FIG. 4 represents the net strain E in the resonator 30. The vertical axis of FIG. 4 represents the polarization ratio.

The polarization ratios of Example 1 and Example 2 in which the wavelength of laser beams was 940 nm were measured.

A method of measuring the polarization ratio is, for example, as follows. Two polarizers are disposed on rays of laser beams, and a change in the intensity of transmitted light is measured while one polarizer is fixed and the other polarizer is rotated. At this time, it is assumed that the maximum intensity of transmitted light is obtained when the orientations of the two polarizers are the same, and the minimum intensity of transmitted light is obtained when the orientations of the two polarizers are orthogonal to each other. When reference character Pmax represents the maximum intensity of transmitted light and reference character Pmin represents the minimum intensity of transmitted light, a polarization ratio A (dB) is obtained by A=10·log(Pmax/Pmin). Example 1 and Example 2 each include the lower spacer layer 31, three quantum well layers 331 and four barrier layers 332 as the active layer 33, and the upper spacer layer 35. The value of the amount εi of strain of each of the lower spacer layer 31 and the upper spacer layer 35 is different between Example 1 and Example 2. In Example 1 and Example 2, an n-GaAs substrate was used as the inclined substrate 10. In Example 1 and Example 2, the lower spacer layer 31 and the upper spacer layer 35 were GaInP layers, the quantum well layer 331 was a GaInAs layer, and the barrier layer 332 was a GaInP layer. Details are as follows.

The composition ratio of In in the spacer layer (the lower spacer layer 31 and the upper spacer layer 35) of Example 1 is larger than the composition ratio of In in the spacer layer (the lower spacer layer 31 and the upper spacer layer 35) of Example 2. Accordingly, the amount of strain in the spacer layer (the lower spacer layer 31 and the upper spacer layer 35) of Example 1 was larger than the amount of strain in the spacer layer (the lower spacer layer 31 and the upper spacer layer 35) of Example 2.

### Example 1

Lower spacer layer 31: amount εi of strain=+0.2%, thickness ti=120 nm
Each quantum well layer 331: amount εi of strain=+0.9%, thickness ti=8 nm
Each barrier layer 332: amount εi of strain=0%, thickness ti=6 nm
Upper spacer layer 35: amount εi of strain=+0.2%, thickness ti=120 nm

$$Net strain E in resonator 30 = about + 69 \% \cdot nm ( = [ ( + 0.2 \% \times 120 nm ) + ( + 0.9 \% \times 8 nm \times 3 layers ) + ( 0 \% \times 6 nm \times 4 layers ) + ( + 0.2 \% \times 120 nm ) ] )$$

### Example 2

Lower spacer layer 31: amount εi of strain=+0.07%, thickness ti=120 nm
Each quantum well layer 331: amount εi of strain=+0.9%, thickness ti=8 nm
Each barrier layer 332: amount εi of strain=0%, thickness ti=6 nm
Upper spacer layer 35: amount εi of strain=+0.07%, thickness ti=120 nm

$$Net strain E in resonator 30 = about + 38 \% \cdot nm ( = [ ( + 0.07 \% \times 120 nm ) + ( + 0.9 \% \times 8 nm \times 3 layers ) + ( 0 \% \times 6 nm \times 4 layers ) + ( + 0.07 \% \times 120 nm ) ] )$$

As presented in FIG. 4, in both Example 1 and Example 2, the polarization ratio exceeded 20 dB. The polarization ratio of 20 dB is, for example, a value as high as that desired in an image forming apparatus such as a laser printer. The polarization ratio of Example 1 increased as compared to the polarization ratio of Example 2. That is, as the amounts εi of strain of the lower spacer layer 31 and the upper spacer layer 35 increased (as the net strain E of the resonator 30 increased), the polarization ratio increased. While both the lower spacer layer 31 and the upper spacer layer 35 have compressive strain in Example 1 and Example 2, based on the above-described results, it is expected that the polarization ratio increases also when one of the lower spacer layer 31 and the upper spacer layer 35 has compressive strain.

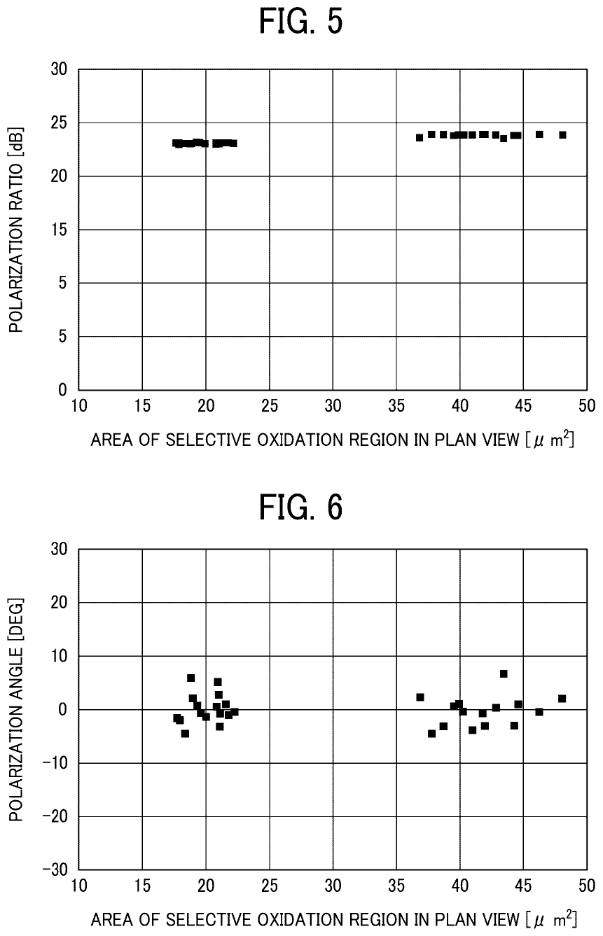

Next, referring to FIGS. 5 and 6, examples of the relationships between the area of the selective oxidation region 412 in the current confinement layer 41 according to Example 1, and the polarization ratio and the polarization direction of laser beams emitted from the surface emitting laser 1 will be described. FIG. 5 is a graph presenting an example of the relationship between the area of the selective oxidation region 412 in the current confinement layer 41 of Example 1 and the polarization ratio of laser beams emitted from the surface emitting laser 1. The horizontal axis of FIG. 5 represents the area of the selective oxidation region 412 in a plan view. The vertical axis of FIG. 5 represents the polarization ratio. FIG. 6 is a graph presenting an example of the relationship between the area of the selective oxidation region 412 in the current confinement layer 41 of Example 1 and the polarization direction of laser beams emitted from the surface emitting laser 1. The horizontal axis of FIG. 6 represents the area of the selective oxidation region 412 in a plan view. The vertical axis of FIG. 6 represents the polarization direction (polarization angle). The direction corresponding to the polarization angle of 0° is the Z-axis direction illustrated in FIG. 1 and so forth.

As presented in FIG. 5, a high polarization ratio exceeding 20 dB was obtained regardless of the area of the selective oxidation region 412 in the current confinement layer 41. As presented in FIG. 6, the change in the polarization direction can be kept within a range of ±10° regardless of the area of the selective oxidation region 412 in the current confinement layer 41. That is, when the net strain E in the resonator 30 was +4.5%·nm or more and +93.0%·nm or less, the stability of the polarization ratio and the polarization direction could be increased regardless of the area of the selective oxidation region 412 in the current confinement layer 41.

### Example 3

Example 3 of the first embodiment will be described. The net strain E in the resonator 30 of Example 3 was about +93.6%·nm. In Example 3, an n-GaAs substrate was used as the inclined substrate 10. The third embodiment includes the lower spacer layer 31, and the active layer 33 including three quantum well layers 331, four barrier layers 332, and the upper spacer layer 35. In Example 3, the lower spacer layer 31 and the upper spacer layer 35 are GaInP layers, the quantum well layer 331 is a GaInAs layer, and the barrier layer 332 is a GaInP layer. The composition ratio of In in the spacer layer (the lower spacer layer 31 and the upper spacer layer 35) of Example 3 is larger than the composition ratio of In in the spacer layer (the lower spacer layer 31 and the upper spacer layer 35) of Example 1. Accordingly, the amount of strain in the spacer layer (the lower spacer layer 31 and the upper spacer layer 35) of Example 3 was larger than the amount of strain in the spacer layer (the lower spacer layer 31 and the upper spacer layer 35) of Example 1.
Lower spacer layer 31: amount εi of strain=+0.3%, thickness ti=120 nm
Each quantum well layer 331: amount εi of strain=+0.9%, thickness ti=8 nm
Each barrier layer 332: amount εi of strain=0%, thickness ti=6 nm
Lower spacer layer 31: amount εi of strain=+0.3%, thickness ti=120 nm
The net strain E in the resonator 30 of Example 3 was about +93.6%·nm.

$$Nm ( = [ ( + 0.3 \% \times 120 nm ) + ( + 0.9 \% \times 8 nm \times 3 layers ) + ( 0 \% \times 6 nm \times 4 layers ) + ( + 0.3 \% \times 120 nm ) ] )$$

The polarization ratio of Example 3 was increased compared to the polarization ratio of Example 1 and the Examples.

### Example 4

Example 4 of the first embodiment will be described. The net strain E in the resonator 30 of Example 4 was about +5.0%·nm. In Example 4, an n-GaAs substrate was used as the inclined substrate 10. Example 4 includes the lower spacer layer 31; the active layer 33 including three quantum well layers 331 and four barrier layers 332; and the upper spacer layer 35. In Example 4, the lower spacer layer 31 and the upper spacer layer 35 are (Al_{0.5}Ga_{0.5})_{0.5}In_{0.5}P layers, the quantum-well layer 331 is a GaInP layer, and the barrier layer 332 is a GaInP layer.
Lower spacer layer 31: amount εi of strain=+0.01%, thickness ti=80 nm
Each quantum well layer 331: amount εi of strain=+0.9%, thickness ti=8 nm
Each barrier layer 332: amount εi of strain=0%, thickness ti=6 nm
Lower spacer layer 31: amount εi of strain=+0.01%, thickness ti=80 nm

$$Net strain E in the resonator 30 = about + 5. \% nm ( = [ ( + 0.01 \% \times 80 nm ) + ( + 0.14 \% \times 8 nm \times 3 layers ) + ( 0 \% \times 6 nm \times 4 layers ) + ( + 0.01 \% \times 80 nm ) ] )$$

### Example 5

Example 5 of the first embodiment will be described. The net strain E in the resonator 30 of Example 5 was about +44.8%·nm. In Example 5, an n-GaAs substrate was used as the inclined substrate 10. Example 5 includes the lower spacer layer 31, the active layer 33 including three quantum well layers 331 and four barrier layers 332, and the upper spacer layer 35. In Example 5, the lower spacer layer 31 and the upper spacer layer 35 are GaInP layers, the quantum well layer 331 is a GaInAs layer, and the barrier layer 332 is a GaInP layer. However, the composition ratio of In in the quantum well layer 331 of Example 5 is smaller than the composition ratio of In in the quantum well layer 331 of Examples 1 to 4. The laser oscillation wavelengths (wavelengths of laser light) of Example 5 were in the 894 nm.
Lower spacer layer 31: amount εi of strain=+0.2%, thickness ti=100 nm
Each quantum well layer 331: amount εi of strain=+0.9%, thickness ti=8 nm
Each barrier layer 332: amount εi of strain=0%, thickness ti=6 nm
Lower spacer layer 31: amount εi of strain=+0.2%, thickness ti=100 nm

$$Net strain E in the resonator 30 = about + 44.8 \% nm ( = [ ( + 0.2 \% \times 100 nm ) + ( + 0.2 \% \times 8 nm \times 3 layers ) + ( 0 \% \times 6 nm \times 4 layers ) + ( + 0.2 \% \times 100 nm ) ] )$$

### Second Embodiment

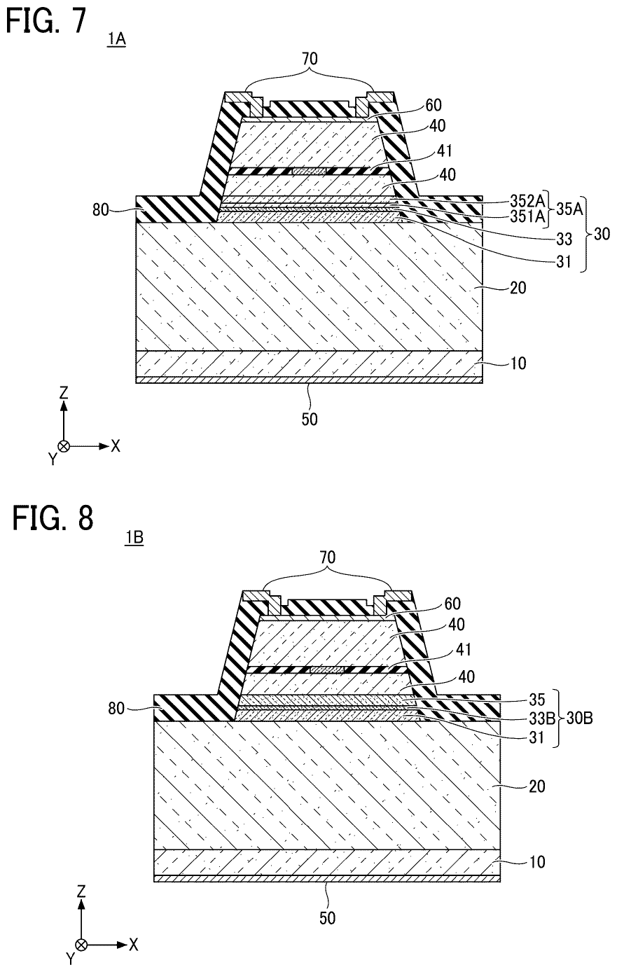

Next, a second embodiment will be described with reference to FIG. 7. FIG. 7 is a cross-sectional view schematically illustrating an example of a surface emitting laser 1A according to the second embodiment. The second embodiment is different from the first embodiment in that an upper spacer layer 35A includes a first layer 351A and a second layer 352A. In the second embodiment, like reference signs are given to components similar to those of the first embodiment. Accordingly, overlapping descriptions are omitted where appropriate.

As illustrated in FIG. 7, the upper spacer layer 35A included in the surface emitting laser 1A includes the first layer 351A and the second layer 352A disposed on the first layer 351A. The first layer 351A has compressive strain. In contrast, the second layer 352A has no lattice strain. The first layer 351A and the second layer 352A may be made of the same material or may be made of different materials.

Although the upper spacer layer 35A includes a portion having no lattice strain, such as the second layer 352A, when at least one of the amount εi of strain and the thickness ti of the first layer 351A having compressive strain is adjusted, the net strain E of the resonator 30 can be adjusted to fall within a desired range. With this configuration, the polarization directions of laser beams can be controlled to a desired direction and stabilized. In addition, the polarization ratio can be increased.

When the first layer 351A and the second layer 352A are made of the same semiconductor material, the second layer 352A has no lattice strain and hence has a larger band gap energy than the first layer 351A having compressive strain. Thus, when a drive voltage is applied to the surface emitting laser 1A, for example, the amount of carriers flowing from a layer located below the upper spacer layer 35A toward the upper reflecting mirror 40 can be reduced. That is, the second layer 352A can function as a carrier block layer. With this configuration, the possibility that carriers overflow in the upper reflecting mirror 40 can be reduced, and the temperature characteristics of the surface emitting laser 1A can be increased.

While the second layer 352A is disposed on the first layer 351A in the example illustrated in FIG. 7, the first layer 351A may be disposed on the second layer 352A. While the upper spacer layer 35A includes the second layer 352A having no lattice strain in the example illustrated in FIG. 7, the lower spacer layer 31 may include a layer having no lattice strain corresponding to the second layer 352A. Each of the lower spacer layer 31 and the upper spacer layer 35A may include a layer having no lattice strain corresponding to the second layer 352A. In other words, one of the lower spacer layer 31 and the upper spacer layer 35A having compressive strain can include a layer having compressive strain (e.g., the first layer 351A) and a layer having no lattice strain (e.g., the second layer 352A).

### Third Embodiment

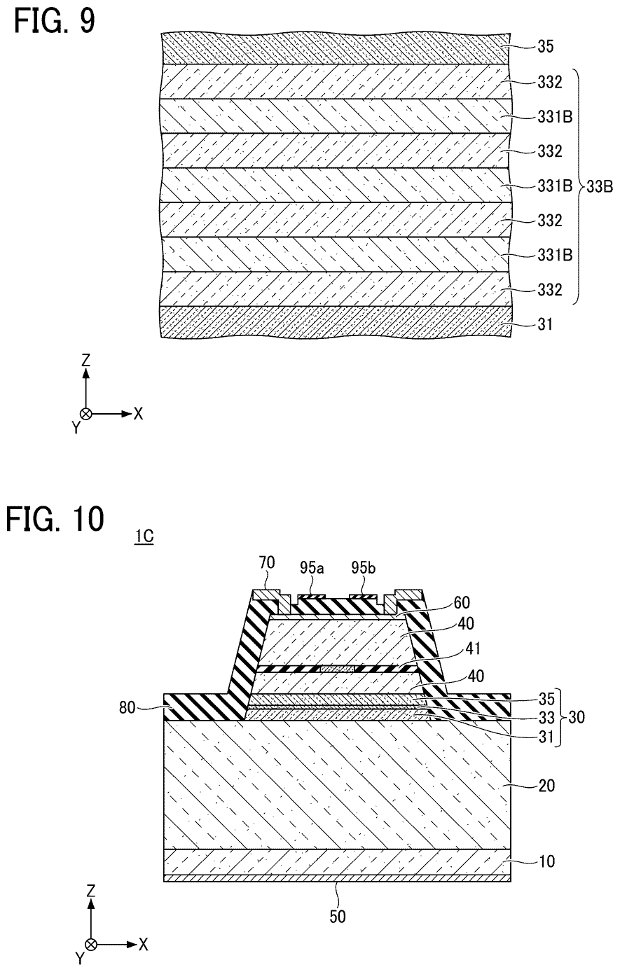

Next, a third embodiment will be described with reference to FIGS. 8 and 9. FIG. 8 is a cross-sectional view schematically illustrating an example of a surface emitting laser 1B according to the third embodiment. FIG. 9 is a cross-sectional view schematically illustrating an example of an active layer 33B included in the surface emitting laser 1B according to the third embodiment. In the third embodiment, a resonator 30B is different from those in the other embodiments. More specifically, the difference is that a quantum well layer 331B of the active layer 33B has tensile strain. In the third embodiment, like reference signs are given to components similar to those of the other embodiments. Accordingly, overlapping descriptions are omitted where appropriate.

The quantum well layer 331B of the active layer 33B is made of, for example, GaInP. Each of the lower spacer layer 31 and the upper spacer layer 35 is made of, for example (Al_{0.5}Ga_{0.5})_{0.5}In_{0.5}P. The quantum well layer 331B has, for example, tensile strain having the absolute value of an amount εi of strain of 1.5% or less. Although the quantum well layer 331B has tensile strain, for example, when the net strain Ei of at least one of the lower spacer layer 31 and the upper spacer layer 35 is increased, the net strain E of the resonator 30 can be adjusted to fall within a desired range. With this configuration, the polarization directions of laser beams can be controlled to a desired direction and stabilized. In addition, the polarization ratio can be increased. With the quantum well layer 331B having tensile strain, laser beams having wavelengths on the short-wavelength side can be emitted from the surface emitting laser 1B as compared to the first embodiment and the second embodiment. Thus, the surface emitting laser 1B according to the third embodiment can be suitably used as, for example, a light emitting device that emits visible light.

### EXAMPLE

Next, the surface-emitting laser 1B according to the third embodiment will be described in more detail using an example. However, the scope of the present disclosure is not limited to the following examples. As an example of the surface-emitting laser 1B according to the third embodiment, the polarization ratio of Example 6 as described below was measured.

### Example 6

Example 6 of the third embodiment will be described.

The net strain E in the resonator 30 of Example 6 was about +4.8%·nm. In Example 6, an n-GaAs substrate was used as the inclined substrate 10. In Example 6, the lower spacer layer 31 and the upper spacer layer 35 are (Al0.5Ga0.5)0.5In0.5P layers, the quantum-well layer 331 is a GaInP layer, and the barrier layer 332 is a GaInP layer.
Lower spacer layer 31: amount εi of strain=+0.165%, thickness ti=80 nm
Each quantum well layer 331B: amount εi of strain=−0.9%, thickness ti=8 nm
Each barrier layer 332: amount εi of strain=0%, thickness ti=6 nm
Upper spacer layer 35: amount εi of strain=+0.165%, thickness ti=80 nm

$$Net strain E in the resonator 30 B = about + 4.8 \% nm ( = [ ( + 0.165 \% \times 80 nm ) + ( - 0.9 \% \times 8 nm \times 3 layers ) + ( 0 \% \times 6 nm \times 4 layers ) + ( + 0.165 \% \times 80 nm ) ] )$$

### Fourth Embodiment

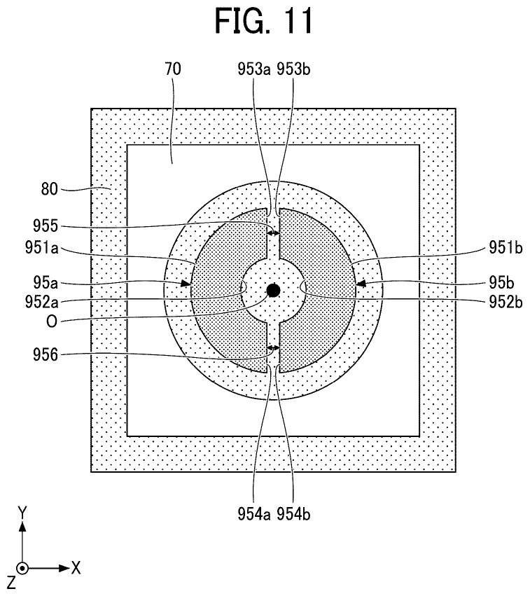

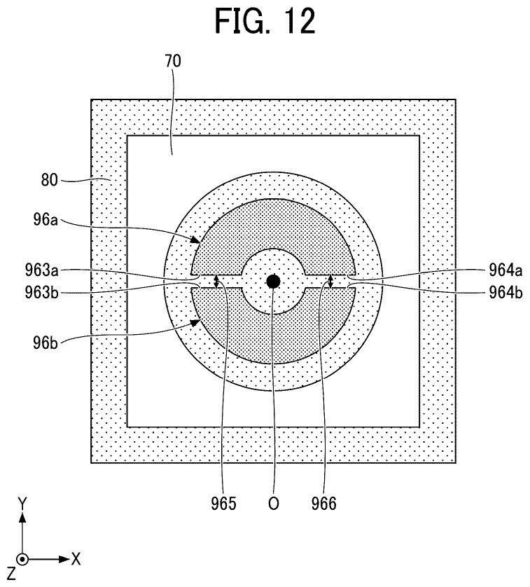

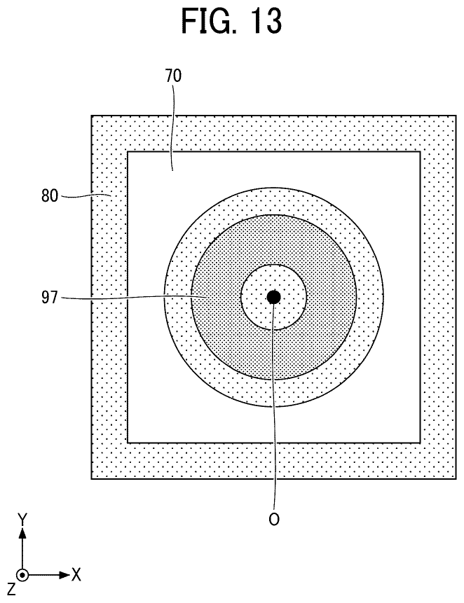

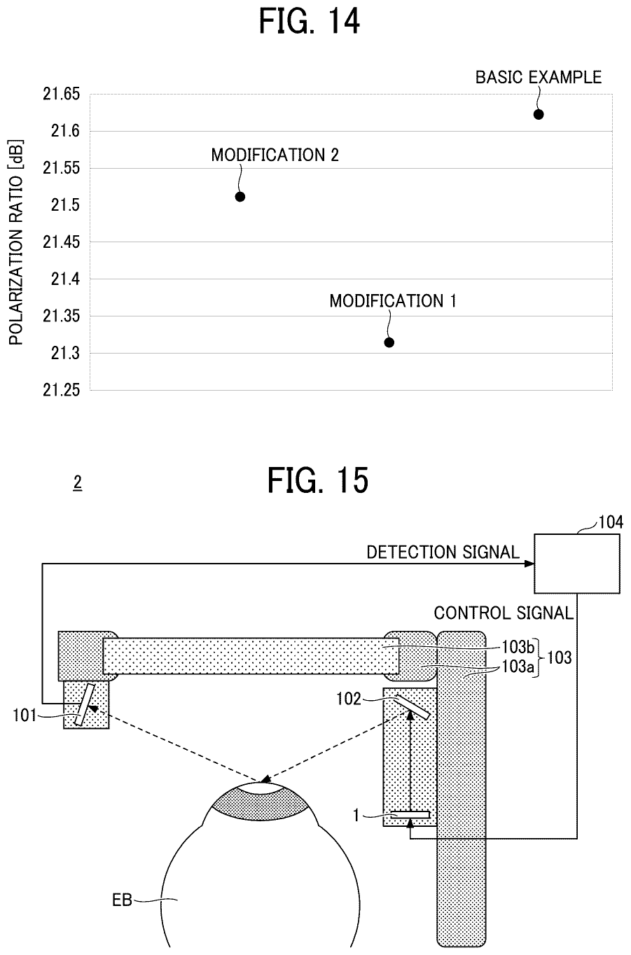

Next, a fourth embodiment will be described with reference to FIGS. 10 to 14. FIG. 10 is a cross-sectional view schematically illustrating an example of a surface emitting laser 1C according to the fourth embodiment. FIG. 11 is a plan view illustrating an example of a pair of dielectric films 95a and 95b (basic example) included in the surface emitting laser 1C. FIG. 12 is a plan view illustrating an example of a pair of dielectric films 96a and 96b according to Modification 1. FIG. 13 is a plan view illustrating an example of a dielectric film 97 according to Modification 2. FIG. 14 is a graph presenting polarization ratios of the basic example, Modification 1, and Modification 2. In the fourth embodiment, like reference signs are given to components similar to those of the other embodiments. Accordingly, overlapping descriptions are omitted where appropriate.

As illustrated in FIG. 10, the surface emitting laser 1C according to the fourth embodiment includes the pair of dielectric films 95a and 95b separated from each other in the in-plane direction. The dielectric films 95a and 95b are films that reduce the reflectivity of a region provided with the dielectric films 95a and 95b to be lower than the reflectivity of a region not provided with the dielectric films 95a and 95b. The pair of dielectric films 95a and 95b are disposed above the upper reflecting mirror 40. In the example illustrated in FIG. 10, the pair of dielectric films 95a and 95b are disposed on the contact layer 60 or on the insulating film 80 covering the contact layer 60. The pair of dielectric films 95a and 95b are located at a top portion of the surface emitting laser 1C.

The dielectric films 95a and 95b have, for example, an optical thickness that is an odd multiple of λ/4. Thus, the reflectivity of the dielectric films 95a and 95b can be made lower than the reflectivity of the upper reflecting mirror 40. When the dielectric films 95a and 95b are disposed on the insulating film 80 covering the contact layer 60, the optical thickness of the insulating film 80 may be an even multiple of λ/2, and the optical thickness of the dielectric films 95a and 95b may be an odd multiple of λ/4. Examples of the dielectric of each of the pair of dielectric films 95a and 95b include SiNₓ, SiOₓ, TiOₓ, and SiON (for example, SiN, SiO₂, and Ta₂O₅). However, the dielectrics included in the dielectric films 95a and 95b are not limited thereto. The dielectrics of the dielectric films 95a and 95b and the dielectric of the insulating film 80 may be the same material.

As illustrated in FIG. 11, the pair of dielectric films 95a and 95b are disposed at positions separated from the center O of the surface emitting laser 1C. The dielectric film 95a has an outer side surface 951a and an inner side surfaces 952a. The dielectric film 95b has an outer side surface 951b and an inner side surface 952b. The outer side surfaces 951a and 951b and the inner side surfaces 952a and 952b are curved in arc shapes in a plan view. The dielectric film 95a has a first end surface 953a and a second end surface 954a. The dielectric film 95b has a first end surface 953b and a second end surface 954b. As illustrated in FIG. 11, each of the first end surface 953a and the second end surface 954a of the dielectric film 95a connects the outer side surface 951a and the inner side surface 952a of the dielectric film 95a to each other. Each of the first end surface 953b and the second end surface 954b of the dielectric film 95b connects the outer side surface 951b and the inner side surface 952b of the dielectric film 95b to each other.

The first end surfaces 953a and 953b of the pair of dielectric films 95a and 95b face each other with a first gap 955 interposed. The second end surfaces 954a and 954b of the pair of dielectric films 95a and 95b face each other with a second gap 956 interposed. In a plan view, the direction in which the first gap 955 and the second gap 956 are arranged coincides with the inclination direction D2 of the inclined substrate 10. In the example illustrated in FIG. 10, in a plan view, the direction in which the first gap 955 and the second gap 956 are arranged coincides with the Y-axis direction.

As with the basic example illustrated in FIGS. 10 and 11, the pair of dielectric films 96a and 96b of Modification 1 illustrated in FIG. 12 are separated from each other in the in-plane direction and disposed at positions separated from the center O. However, in Modification 1, a direction in which a first gap 965 between first end surfaces 963a and 963b and a second gap 966 between second end surfaces 964a and 964b of the pair of dielectric films 96a and 96b are arranged is orthogonal to the inclination direction D2 in a plan view.

Modification 2 illustrated in FIG. 13 includes the dielectric film 97 that does not have gaps corresponding to the first gaps 955 and 965 and the second gaps 956 and 966 and that has an annular structure disposed around the center O.

Referring to FIG. 14, measurement results relating to polarization ratios of the basic example, Modification 1, and Modification 2 will be described. The vertical axis of FIG. 14 represents the polarization ratio. As presented in FIG. 14, a high polarization ratio exceeding 20 dB was obtained in each of the basic example, Modification 1, and Modification 2. Among them, the polarization ratio of the basic example was higher than those of the other examples. From this, it was confirmed that, when the first gap 955 and the second gap 956 were arranged so as to coincide with the inclination direction D2 of the inclined substrate 10, the polarization ratio was increased.

### Fifth Embodiment

Next, a fifth embodiment will be described with reference to FIG. 15. FIG. 15 is a plan view schematically illustrating an example of an eyeball-tilt-position detecting device 2 according to the fifth embodiment.

As illustrated in FIG. 15, the eyeball-tilt-position detecting device 2 includes the surface emitting laser 1 according to the first embodiment and a photodetector 101 that detects reflected light emitted from the surface emitting laser 1 and reflected by an eyeball EB. The surface emitting laser included in the eyeball-tilt-position detecting device 2 may be any one of the surface emitting lasers 1A, 1B, and 1C according to the second to fourth embodiments.

The number of surface emitting lasers included in the eyeball-tilt-position detecting device 2 is not limited to one, and may be two or more.

Examples of the photodetector 101 include one-dimensional and two-dimensional position sensitive detectors (PSDs), and imaging elements such as a charge coupled device (CCD) and a complementary metal oxide semiconductor (CMOS).

In the example illustrated in FIG. 15, the eyeball-tilt-position detecting device 2 further includes an optical deflector 102 that deflects laser beams emitted from the surface emitting laser 1, a support 103, and a controller 104. Examples of the optical deflector 102 include a plane mirror, a convex lens, a microlens array, a concave curved-surface mirror, a hologram diffraction element, a prism array, and a diffraction grating. The optical deflector 102 may be any one of a plane mirror, a convex lens, a microlens array, a concave curved-surface mirror, a hologram diffraction element, a prism array, and a diffraction grating, or may be a combination of any two or more of them.

For example, the support 103 is worn on a head portion of a user. In the example illustrated in FIG. 15, the support 103 includes an eyeglass frame 103a and an eyeglass lens 103b. The support 103 can support the surface emitting laser 1, the photodetector 101, and the optical deflector 102. However, the configuration of the support 103 is not limited to the example illustrated in FIG. 15.

The controller 104 controls the operation of the eyeball-tilt-position detecting device 2. The controller 104 includes, for example, a processor such as a central processing unit (CPU) and a storage medium such as a read only memory (ROM). The processor of the controller 104 executes desired processing (for example, processing for detecting the tilt position of the eyeball EB) in accordance with a program stored in the storage medium such as the ROM. As illustrated in FIG. 15, the controller 104 acquires a detection signal output from the photodetector 101 and outputs a control signal to, for example, the surface emitting laser 1.

The light emitted from the surface emitting laser 1 is deflected by the optical deflector 102 and then incident on the cornea of the eyeball EB. The light incident on the cornea of the eyeball EB is reflected toward the photodetector 101. The photodetector 101 receives the reflected light and outputs a detection signal corresponding to the intensity of the received light to the controller 104. The controller 104 detects the tilt position of the eyeball EB based on the detection signal.

With the eyeball-tilt-position detecting device 2, the intensity of laser beams emitted from the surface emitting laser 1 is limited in order to satisfy a safety standard such as eye safety. As described above, the light emitted from the surface emitting laser 1 has a stable polarization direction and a high polarization ratio. Thus, even when the intensity of laser beams emitted from the surface emitting laser 1 is relatively low, the intensity of the reflected light having reached the photodetector 101 can be ensured. With this configuration, while the safety standard of laser beams emitted from the surface emitting laser 1 is satisfied, the possibility that the reflected light having reached the photodetector 101 from the cornea of the eyeball EB is not detected can be reduced. From this viewpoint, the polarization ratio of the surface emitting laser (the surface emitting laser 1 in FIG. 15) included in the eyeball-tilt-position detecting device 2 is preferably 20 dB or more.

When the eyeball-tilt-position detecting device 2 operates, in order to prevent the laser beams emitted from the surface emitting laser 1 from being recognized by the user, the wavelength of the laser beams emitted from the surface emitting laser 1 is preferably, for example, 780 nm or more. From the viewpoint that a light receiver made of Si can be used as the photodetector 101, the wavelength of the laser beams emitted from the surface emitting laser 1 is preferably 940 nm. In the present embodiment, adjusting the amount εi of strain of the active layer 33 can adjust the wavelength of the laser beams emitted from the surface emitting laser 1.

### Sixth Embodiment

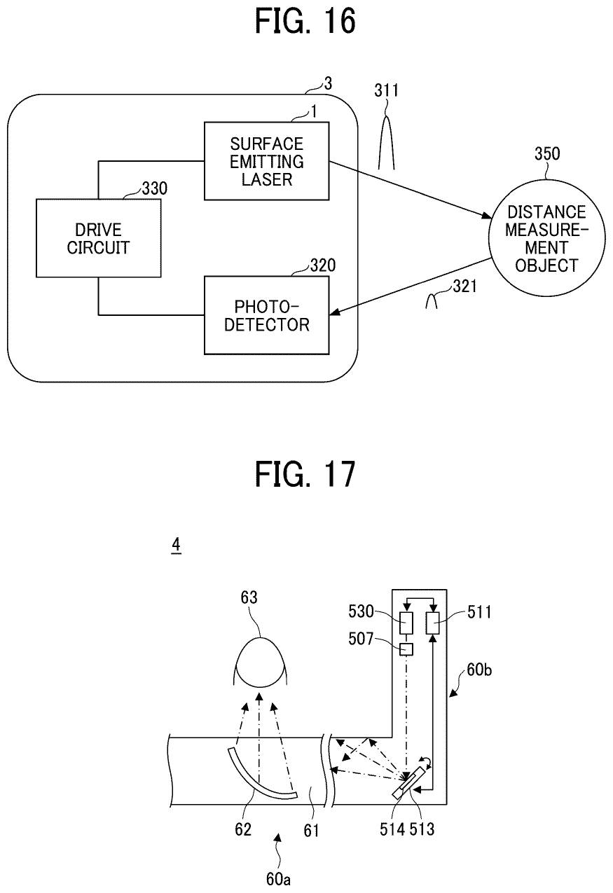

Next, a sixth embodiment will be described with reference to FIG. 16. FIG. 16 is a block diagram schematically illustrating an example of a distance measuring device 3 according to the sixth embodiment.

The distance measuring device 3 according to the sixth embodiment is a distance measuring device using a time of flight (TOF) method. The distance measuring device 3 includes the surface emitting laser 1, a photodetector 320, and a drive circuit 330. The surface emitting laser included in the distance measuring device 3 may be any one of the surface emitting lasers 1A, 1B, and 1C according to the second to fourth embodiments. The number of surface emitting lasers included in the distance measuring device 3 is not limited to one, and may be two or more.

The photodetector 320 detects reflected light emitted from the surface emitting laser 1 and reflected by an object (a distance measurement object 350). Examples of the photodetector 320 include a photodiode, an avalanche photodiode, and a single-photon avalanche diode. The photodetector 320 may include a plurality of light receivers arranged in an array.

As illustrated in FIG. 16, the surface emitting laser 1 emits a laser beam 311 to the distance measurement object 350. The photodetector 320 receives reflected light 321 from the distance measurement object 350. The drive circuit 330 drives the surface emitting laser 1 and detects the difference in time between the emission timing of the laser beam 311 and the reception timing of the reflected light 321 by the photodetector 320 to measure the distance of reciprocation to and from the distance measurement object 350.

With the present embodiment, the polarization direction of the laser beam 311 emitted from the surface emitting laser (the surface emitting laser 1 in FIG. 16) included in the distance measuring device 3 can be easily controlled to a specific direction. Thus, when the polarization direction of the laser beam 311 and the incident direction on a transparent body are adjusted, the possibility that the laser beam 311 is reflected by the transparent body and does not reach the distance measurement object 350 can be reduced. With this, a decrease in the detection accuracy of the distance measurement object 350 can be prevented.

The polarization ratio of the surface emitting laser 1 included in the distance measuring device 3 is preferably 20 dB or more. When the distance measuring device 3 operates, in order to prevent the laser beam emitted from the surface emitting laser 1 from being recognized by the user, the wavelength of the laser beam emitted from the surface emitting laser 1 is preferably, for example, 780 nm or more. From the viewpoint that a light receiver made of Si can be used as the photodetector 320, the laser beam emitted from the surface emitting laser 1 preferably has a wavelength of 940 nm. Adjusting the amount εi of strain of the active layer 33 can adjust the wavelength of the laser beam emitted from the surface emitting laser 1.

### Seventh Embodiment

Next, a seventh embodiment will be described with reference to FIG. 17. FIG. 17 is a diagram schematically illustrating an example of a head mount display 4 according to the seventh embodiment. The head mount display 4 is an example of a “display device.”

The head mount display 4 is an example of a head mount display device that can be mounted on a head portion of a person, and can be shaped like, for example, eyeglasses. Hereinafter, the head mount display 4 will be abbreviated as HMD 4.

In FIG. 17, the HMD 4 includes a front 60a and a temple 60b. The front 60a can include, for example, a light guide plate 61. An optical system, a control device, and so forth, can be incorporated in the temple 60b.

The HMD 4 includes a control device 511, a light source unit 530, a light-intensity adjuster 507, a movable device 513 having a reflecting surface 514, the light guide plate 61, and a semi-reflective mirror 62.

The light source unit 530 includes a red laser beam source, a green laser beam source, a blue laser beam source, a plurality of collimator lenses, and a plurality of dichroic mirrors, which are combined as a single unit in an optical housing. In the light source unit 530, the laser beams of three colors from the red laser beam source, the green laser beam source, and the blue laser beam source are combined by a dichroic mirror. The light source unit 530 emits combined parallel beams.

The red laser beam source includes one or two or more surface emitting lasers according to any one of the first to fourth embodiments, and emits red laser beams. The green laser beam source includes one or two or more surface emitting lasers according to any one of the first to fourth embodiments, and emits green laser beams. The blue laser beam source includes one or two or more surface emitting lasers according to any one of the first to fourth embodiments, and emits blue laser beams.

The light intensity of the combined laser beams from the light source unit 530 is adjusted by the light-intensity adjuster 507. Then, the adjusted light is incident on the movable device 513. Based on a signal from the control device 511, the movable device 513 moves the reflecting surface 514 to perform two-dimensional scanning with the light from the light source unit 530. The driving of the movable device 513 is controlled in synchronization with the emission timings of the red laser beam source, the green laser beam source, and the blue laser beam source.

The scanning light of the movable device 513 is incident on the light guide plate 61. The light guide plate 61 reflects the scanning light on the inner wall and guides the scanning light to the semi-reflective mirror 62. The light guide plate 61 is made of, for example, resin that has transparency to the wavelength of the scanning light.

The semi-reflective mirror 62 reflects the light from the light guide plate 61 toward the rear surface side of the HMD 4 and emits the light in the direction toward the eye of a wearer 63 of the HMD 4. The semi-reflective mirror 62 has, for example, a free-form curved-surface shape. An image formed with the scanning light is reflected by the semi-reflective mirror 62, thus being formed on the retina of the wearer 63. Alternatively, with the reflection by the semi-reflective mirror 62 and the lens effect of the crystalline lens in the eyeball, an image is formed on the retina of the wearer 63. Moreover, due to the reflection at the semi-reflective mirror 62, the spatial distortion of the image is corrected. The wearer 63 can visually identify the image formed with the light through scanning.

The wearer 63 visually identifies an image of external light superposed on the image of the scanning light because the semi-reflective mirror 62 is used. Alternatively, a mirror may be provided instead of the semi-reflective mirror 62 to block out external light and enable the wearer 63 to visually identify the image of the scanning light.

### Eighth Embodiment

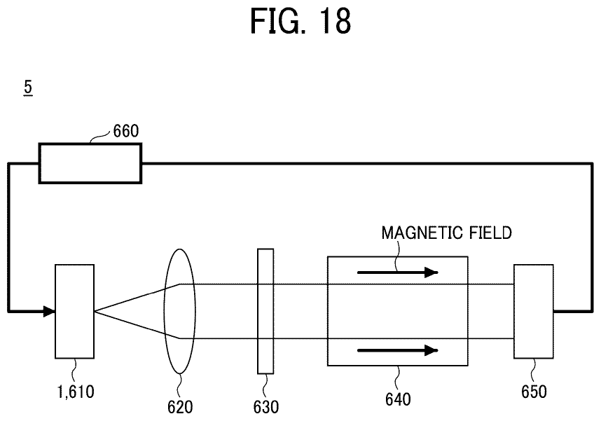

An eighth embodiment is described below with reference to FIGS. 18 to 21.

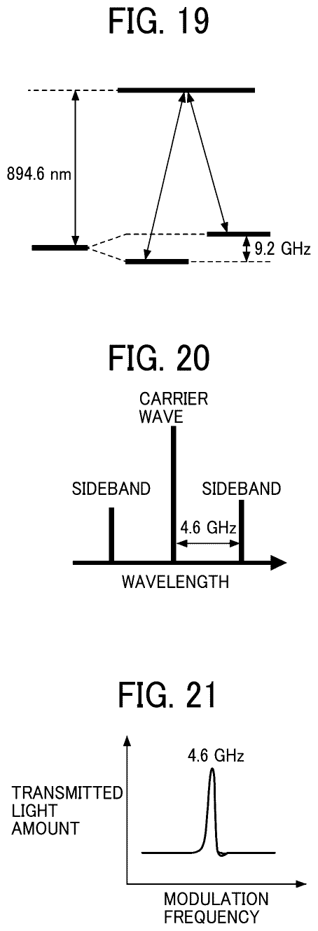

FIG. 18 is a diagram schematically illustrating an example of an atomic oscillator 5 according to the eighth embodiment. FIG. 19 is a diagram illustrating an example of an atomic energy level for explaining the coherent population trapping (CPT). FIG. 20 is a diagram illustrating an example of an output wavelength at the time of modulation of the surface emitting laser 1. FIG. 21 is a diagram illustrating an example of a relationship between a modulation frequency and a transmitted light amount.

The atomic oscillator 5 is a small atomic oscillator of a CPT type, and includes a light source 610, a collimator lens 620, a λ/4 wave plate 630, an alkali metal cell 640, a light detector 650, and a modulator 660. The light source 610 includes the surface emitting laser 1 according to the first embodiment. However, the surface emitting laser included in the optical source 610 may be any one of the surface emitting lasers 1A, 1B, and 1C according to the second to fourth embodiments.

The alkali metal cell 640 contains cesium (Cs) atomic gas as an alkali metal, and uses a transition of a D1 line. The light detector 650 includes, for example, a photodiode. In the atomic oscillator 5, light (laser light) emitted from the light source 610 is emitted onto the alkali metal cell 640 in which cesium atomic gas is enclosed, and electrons in the cesium atoms are excited. The light detector 650 detects light that is emitted from the surface emitting laser 1 and transmitted through the alkali metal cell 640. In addition, a signal detected by the light detector 650 is fed back to the modulator 660, and the modulator 660 modulates the surface emitting laser 1 included in the light source 610.

FIG. 19 illustrates a structure of atomic energy levels related to CPT. In the atomic oscillator 5 employing a CPT scheme, when electrons are simultaneously excited from two ground states to an excited state, a decrease in a light absorption rate is utilized. When a device having a carrier-wave wavelength close to 894.6 nm is used as the surface emitting laser 1, a wavelength of the carrier wave can be tuned by changing a temperature or an output of the surface emitting laser 1. Since the wavelength shifts to a longer wavelength when the temperature or the output is increased, the change in the light density of the alkaline metal cell 640 is not preferable, and thus it is preferable to use the temperature change. Specifically, the temperature dependence of the wavelengths can be adjusted by about 0.05 nm/° C.

As illustrated in FIG. 20, sidebands are generated on both sides of a carrier wave by applying modulation, and the modulation is performed at 4.6 GHz so that a frequency difference between the sidebands corresponds to 9.2 GHz, which is a natural oscillation frequency of cesium atoms.

As illustrated in FIG. 21, light passing through the excited cesium atomic gas becomes maximum when a sideband frequency difference corresponds to a natural frequency difference of the cesium atoms. Accordingly, feedback is performed in the modulator 660 so that an output of the light detector 650 maintains a maximum value, and a modulation frequency of the surface emitting laser 1 in the light source 610 is adjusted. Since the natural frequency of the atom is extremely stable, the modulation frequency becomes a stable value, and this information is taken out as an output.

The atomic oscillator 5 according to the present embodiment uses the surface emitting laser 1, in which the polarization direction has been stabilized as described above. This provides a highly time-stable atomic oscillator 5. In the present embodiment, cesium is used as an alkali metal and a transition of its D1 line is used; thus, the surface emitting laser 1 having a wavelength of 894.6 nm is employed. However, when a D2 line of cesium is used, light having a wavelength of 852.3 nm can also be employed. In addition, rubidium (Rb) can also be used as the alkali metal, and when a D1 line is used, light having a wavelength of 795.0 nm can be employed. In addition, when a D2 line is used, light having a wavelength of 780.2 nm can be employed. A material composition of the active layer 33 can be designed as appropriate in accordance with the wavelength of the light. In addition, when rubidium is used, a modulation frequency is 3.4 GHz for 87 Rb and 1.5 GHz for 85 Rb. When a wavelength of light emitted from the surface emitting laser 1 is shorter than 890 nm, an absolute value of strain εi of the quantum well layer 331 needs to be reduced. However, a polarization direction can be stabilized by performing adjustments such as increasing strain Fi of the lower spacer layer 31 and the upper spacer layer 35.

A surface emitting laser includes an inclined substrate (10); a first reflecting mirror (20) over the inclined substrate (10) in an emission direction; a resonator (30) over the first reflecting mirror (20) in the emission direction; and a second reflecting mirror (40) over the resonator (30) in the emission direction. The resonator (30) includes: a first spacer layer (31) over the first reflecting mirror (20) in the emission direction; an active layer (33) over the first spacer layer in the emission direction; and a second spacer layer (35) over the active layer in the emission direction. At least one of the first spacer layer or the second spacer layer has compressive strain. The resonator (30) has a net strain of +4.5%·nm or more and +93.6%·nm or less.

The active layer (33) includes a quantum well layer (331); and a barrier layer (332). The quantum well layer (331) has an amount of strain of 0% or more and +1.5% or less.

The active layer (33) includes: a quantum well layer (331); and a barrier layer (332). The quantum well layer (331) has an amount of strain of −1.5% or more and 0% or less.

The at least one of the first spacer layer (31) or the second spacer layer (35) has the compressive strain. The second spacer layer (35) includes a first layer (351A) having the compressive strain; and a second layer (352A) having no lattice strain.

The surface emitting laser further includes a pair of a first dielectric film (95a) and a second dielectric film (95b). The pair of the first dielectric film (95a) and the second dielectric film (95b) are disposed above the second reflecting mirror (40) and separated from each other in an in-plane direction (X). The first dielectric film (95a) has a first outer side surface (951a); a first inner side surface (952a); an A-first end face (953a); and an A-second end face (954a). The second dielectric film (95b) has a second outer side surface (951b); a second inner side surface (952b); a B-first end face (953b); and a B-second end face (954b). The A-first end face (953a) connects each of one end of the first outer side surface (951a) and the first inner side surface (952a) with each other, and the A-second end face (954a) connects each of another end of the first outer side surface (951a) and the first inner side surface (952a) with each other, to form a first annular region. The B-first end face (953b) connects each of one end of the second outer side surface (951b) and the second inner side surface (952b) with each other, and the B-second end face (954b) connects each of another end of the second outer side surface (951b) and the second inner side surface (952b) with each other, to form a second annular region. The A-first end face (953a) and the B-first end face (953b) face each other with a first gap (955) therebetween. The A-second end face (954a) and the B-second end face (954b) face each other with a second gap (956) therebetween. The first gap and the second gap are arranged in a direction (Y) parallel to an inclined direction (D2) of the inclined substrate (10) in a plan view of the surface emitting laser.

The surface emitting laser has a polarization ratio of 20 dB or more.

An eyeball-tilt-position detecting device (2) includes the surface emitting laser; and a photodetector (101) to detect reflected light emitted from the surface emitting laser and reflected from an eyeball.

A distance measuring device includes the surface emitting laser (1); and a photodetector (101) to detect reflection light emitted from the surface emitting laser and reflected from an object.

A display device comprising the surface emitting laser.

An atomic oscillator includes the surface emitting laser (1); an alkali metal cell (640) in which an alkali metal is sealed; and a light detector (650) to detect light emitted from the surface emitting laser and passed through the alkali metal cell.

Although the desirable embodiments and so forth have been described in detail, the present disclosure is not limited to the above-described embodiments and so forth, and various modifications and substitutions can be made without departing from the scope and spirit of the present disclosure as set forth in the claims.

Aspects of the present disclosure are, for example, as follows.

According to Aspect 1, a surface emitting laser includes an inclined substrate; a lower reflecting mirror disposed on the inclined substrate; a resonator disposed on the lower reflecting mirror; and an upper reflecting mirror disposed on the resonator. The resonator includes a lower spacer layer disposed on the lower reflecting mirror; an active layer disposed on the lower spacer layer; and an upper spacer layer disposed on the active layer. At least one of the lower spacer layer or the upper spacer layer has compressive strain. The resonator has a net strain of +4.5%·nm or more and +93.6%·nm or less.

According to Aspect 2, in the surface emitting laser of Aspect 1, the active layer includes a quantum well layer; and a barrier layer, and the quantum well layer has an amount of strain of 0% or more and +1.5% or less.

According to Aspect 3, in the surface emitting laser of Aspect 1, the active layer includes a quantum well layer; and a barrier layer, and the quantum well layer has an amount of strain of −1.5% or more and 0% or less.

According to Aspect 4, in the surface emitting laser of any one of Aspect 1 to Aspect 3, the at least one of the lower spacer layer or the upper spacer layer having the compressive strain includes a first layer having the compressive strain and a second layer having no lattice strain.

According to Aspect 5, the surface emitting laser of any one of Aspect 1 to Aspect 4 further includes a pair of dielectric films disposed above the upper reflecting mirror and separated from each other in an in-plane direction. Each of the pair of dielectric films has an outer side surface, an inner side surface, and two end surfaces including a first end surface and a second end surface each connecting the outer side surface and the inner side surface to each other. The first end surfaces of the pair of dielectric films face each other with a first gap interposed. The second end surfaces of the pair of dielectric films face each other with a second gap interposed. A direction in which the first gap and the second gap are arranged coincides with an inclination direction of the inclined substrate in a plan view.

According to Aspect 6, in the surface emitting laser of any one of Aspect 1 to Aspect 5, the surface emitting laser has a polarization ratio of 20 dB or more.

According to Aspect 7, an eyeball-tilt-position detecting device includes the surface emitting laser of any one of Aspect 1 to Aspect 6; and a photodetector that detects reflected light emitted from the surface emitting laser and reflected by an eyeball.

According to Aspect 8, a distance measuring device includes the surface emitting laser of any one of Aspect 1 to Aspect 6; and a photodetector that detects reflected light emitted from the surface emitting laser and reflected by an object.

According to Aspect 9, a display device includes the surface emitting laser of any one of Aspect 1 to Aspect 6.

According to Aspect 10, an atomic oscillator includes the surface emitting laser according to any one of Aspect 1 to Aspect 6; an alkali metal cell in which an alkali metal is sealed; and a light detector to detect light emitted from the surface emitting laser and passing through the alkali metal cell.

The above-described embodiments are illustrative and do not limit the present invention. Thus, numerous additional modifications and variations are possible in light of the above teachings. For example, elements and/or features of different illustrative embodiments may be combined with each other and/or substituted for each other within the scope of the present invention.

1. A surface emitting laser comprising:
an inclined substrate;
a first reflecting mirror over the inclined substrate in an emission direction;
a resonator over the first reflecting mirror in the emission direction; and
a second reflecting mirror over the resonator in the emission direction, wherein:
the resonator includes:
a first spacer layer over the first reflecting mirror in the emission direction;
an active layer over the first spacer layer in the emission direction; and
a second spacer layer over the active layer in the emission direction,
wherein:
at least one of the first spacer layer or the second spacer layer has compressive strain, and
the resonator has a net strain of +4.5%·nm or more and +93.6%·nm or less.

2. The surface emitting laser according to claim 1, wherein:
the active layer includes:
a quantum well layer; and
a barrier layer, and
the quantum well layer has an amount of strain of 0% or more and +1.5% or less.

3. The surface emitting laser according to claim 1, wherein:
the active layer includes:
a quantum well layer; and
a barrier layer, and
the quantum well layer has an amount of strain of −1.5% or more and 0% or less.

4. The surface emitting laser according to claim 1, wherein:
the at least one of:
the first spacer layer; or
the second spacer layer,
has the compressive strain; and
the second spacer layer includes:
a first layer having the compressive strain; and
a second layer having no lattice strain.

5. The surface emitting laser according to claim 1, further comprising:
a pair of:
a first dielectric film; and
a second dielectric film,
the pair of the first dielectric film and the second dielectric film being:
disposed above the second reflecting mirror and;
separated from each other in an in-plane direction,
the first dielectric film having:
a first outer side surface;
a first inner side surface;
an A-first end face; and
an A-second end face,
the second dielectric film having:
a second outer side surface;
a second inner side surface;
a B-first end face; and
a B-second end face, wherein:
the A-first end face connects each of one end of the first outer side surface and the first inner side surface with each other; and
the A-second end face connects each of another end of the first outer side surface and the first inner side surface with each other,
to form a first annular region,
the B-first end face connects each of one end of the second outer side surface and the second inner side surface with each other,
the B-second end face connects each of another end of the second outer side surface and the second inner side surface with each other,
to form a second annular region,
the A-first end face and the B-first end face each other with a first gap therebetween,
the A-second end face and the B-second end face each other with a second gap therebetween, and
the first gap and the second gap are arranged in a direction parallel to an inclined direction of the inclined substrate in a plan view of the surface emitting laser.

6. The surface emitting laser according to claim 1, wherein:
the surface emitting laser has a polarization ratio of 20 dB or more.

7. An eyeball-tilt-position detecting device comprising:
the surface emitting laser according to claim 1; and
a photodetector to detect reflected light emitted from the surface emitting laser and reflected from an eyeball.

8. A distance measuring device comprising:
the surface emitting laser according to claim 1; and
a photodetector to detect reflection light emitted from the surface emitting laser and reflected from an object.

9. A display device comprising the surface emitting laser according to claim 1.

10. An atomic oscillator comprising:
the surface emitting laser according to claim 1;
an alkali metal cell in which an alkali metal is sealed; and
a light detector to detect light emitted from the surface emitting laser and passed through the alkali metal cell.
